(19) United States
(12) Patent Application Publication
(10) Pub. No.: US 2025/0259887 A1
(43) Pub. Date: Aug. 14, 2025

(54) METHOD FOR MANUFACTURING SEMICONDUCTOR DEVICE

(71) Applicant: Kioxia Corporation, Tokyo (JP)

(72) Inventor: Mitsuhiro OMURA, Nagoya Aichi (JP)

(73) Assignee: Kioxia Corporation, Tokyo (JP)

(21) Appl. No.: 18/818,964

(22) Filed: Aug. 29, 2024

(30) Foreign Application Priority Data
Feb. 14, 2024 (JP) 2024-020511

(51) Int. Cl. H01L 21/768; H01L 21/02; H01L 21/311

(52) U.S. Cl. CPC H01L 21/76834; H01L 21/02164; H01L 21/0223; H01L 21/02252; H01L 21/31116; H01L 21/76814

(57) ABSTRACT

A method for manufacturing a semiconductor device includes preparing a substrate having a film to be processed, forming a recess on the film to be processed by performing a first etching process by plasma using a gas containing hydrogen fluoride, forming a first protective layer containing nitrogen, hydrogen, and fluorine by supplying a gas containing nitrogen and hydrogen to the recess without applying high frequency power, and performing a second etching process to the recess in which the first protective layer is formed thereon by the plasma.

### CROSS-REFERENCE TO RELATED APPLICATION(S)

This application is based upon and claims the benefit of priority from the prior Japanese Patent Application No. 2024-020511, filed on Feb. 14, 2024, the entire contents of which are incorporated herein by reference.

### FIELD

Embodiments described herein relate generally to a method for manufacturing a semiconductor device.

### BACKGROUND

Semiconductor packages using NAND type flash memories as semiconductor devices are known. In order to increase the capacity of such a NAND type flash memory, a three-dimensional NAND type flash memory having a structure in which many memory cells are stacked has been put into practical use. In such a stacked three-dimensional NAND type flash memory, the number of stacked layers continues to increase in order to achieve high integration, and a technique for forming a high aspect ratio pattern (a hole or a groove) corresponding thereto is required.

### BRIEF DESCRIPTION OF THE DRAWINGS

FIG. 1 is a perspective view showing an overall configuration of a semiconductor device according to an embodiment.

FIG. 2 is a cross-sectional view showing an overall configuration of a semiconductor device according to an embodiment.

FIG. 3 is a cross-sectional view showing a configuration of a memory cell of a semiconductor device according to an embodiment.

FIG. 4A is a cross-sectional view showing a method for manufacturing a semiconductor device according to an embodiment.

FIG. 4B is a cross-sectional view showing a method for manufacturing a semiconductor device according to an embodiment.

FIG. 4C is a cross-sectional view showing a method for manufacturing a semiconductor device according to an embodiment.

FIG. 4D is a cross-sectional view showing a method for manufacturing a semiconductor device according to an embodiment.

FIG. 4E is a cross-sectional view showing a method for manufacturing a semiconductor device according to an embodiment.

FIG. 5 is a diagram explaining a method for manufacturing a semiconductor device according to an embodiment.

FIG. 6A is a cross-sectional view showing a method for manufacturing a semiconductor device according to an embodiment.

FIG. 6B is a cross-sectional view showing a method for manufacturing a semiconductor device according to an embodiment.

FIG. 7 is a diagram explaining a method for manufacturing a semiconductor device according to an embodiment.

FIG. 8A is a cross-sectional view showing a method for manufacturing a semiconductor device according to an embodiment.

FIG. 8B is a cross-sectional view showing a method for manufacturing a semiconductor device according to an embodiment.

FIG. 9 is a diagram explaining a method for manufacturing a semiconductor device according to an embodiment.

FIG. 10 is a cross-sectional view showing a method for manufacturing a semiconductor device according to an embodiment.

FIG. 11 a diagram explaining a method for manufacturing a semiconductor device according to an embodiment.

FIG. 12 is a schematic diagram showing a configuration of a semiconductor manufacturing apparatus according to an embodiment.

### DESCRIPTION OF EMBODIMENTS

Hereinafter, a method for manufacturing a semiconductor device according to the present embodiment will be specifically described with reference to the drawings. In the following description, elements having substantially the same functions and configurations are denoted by the same reference signs or the same reference signs followed by alphabetic characters, and will be described redundantly only when necessary. Each of the embodiments described below exemplifies a device and a method for embodying the technical idea of this embodiment. Various modifications may be made to one embodiment without departing from the spirit of the disclosure. These embodiments and modifications thereof are included in the scope of the disclosure described in the claims and equivalents thereof.

In the drawings, although the widths, thicknesses, shapes, and the like of the respective portions may be schematically represented in comparison with the actual embodiments for clarity of explanation, the drawings are merely examples, and do not limit the interpretation of the present disclosure. In the present specification and the drawings, elements having the same functions as those described with respect to the previous drawings are denoted by the same reference signs, and redundant descriptions thereof may be omitted.

In each embodiment of the present disclosure, a direction from the substrate toward the memory cell is referred to as an upward direction. Conversely, a direction from the memory cell toward the substrate is referred to as a downward direction. As described above, for convenience of explanation, although the term “upper” or “lower” is used for description, for example, the substrate and the memory cell may be arranged such that the vertical relationship between the substrate and the memory cell is opposite to that shown in the drawings. Further, in the following description, for example, the expression “memory cell above the substrate” merely describes the vertical relationship between the substrate and the memory cell as described above, and other members may be arranged between the substrate and the memory cell.

In the present specification, the expression “a includes A, B, or C” does not exclude a case where α includes a plurality of combinations of A to C unless otherwise specified. Furthermore, these expressions do not exclude the case where α includes other materials.

The following embodiments can be combined with each other as long as there is no technical inconsistency.

In the following embodiments, although a memory cell array is exemplified as a semiconductor device, the disclosed technique can be applied to a semiconductor device other than the memory cell array (for example, a CPU, a display, an interposer, or the like).

Further, in the following embodiments, the configuration of the peripheral (CMOS) circuit is not particularly mentioned. In the semiconductor device, the CMOS circuit may be partitioned into other regions of the semiconductor substrate. Further, in the semiconductor device, the CMOS circuit chip and the memory cell array chip may be separately formed on different semiconductor substrates. The upper surface of the memory cell array chip and the upper surface of the CMOS circuit chip may be bonded to each other. In addition, the memory cell array may be integrally formed on the CMOS circuit chip.

A method for manufacturing a semiconductor device according to an embodiment includes preparing a substrate having a film to be processed, forming a recess on the film to be processed by performing a first etching process by plasma using a gas containing hydrogen fluoride, forming a first protective layer containing nitrogen, hydrogen, and fluorine by supplying a gas containing nitrogen and hydrogen to the recess without applying a high frequency power, and performing a second etching process to the recess in which the first protective layer is formed thereon by the plasma.

### First Embodiment

[Configuration of Semiconductor Device]

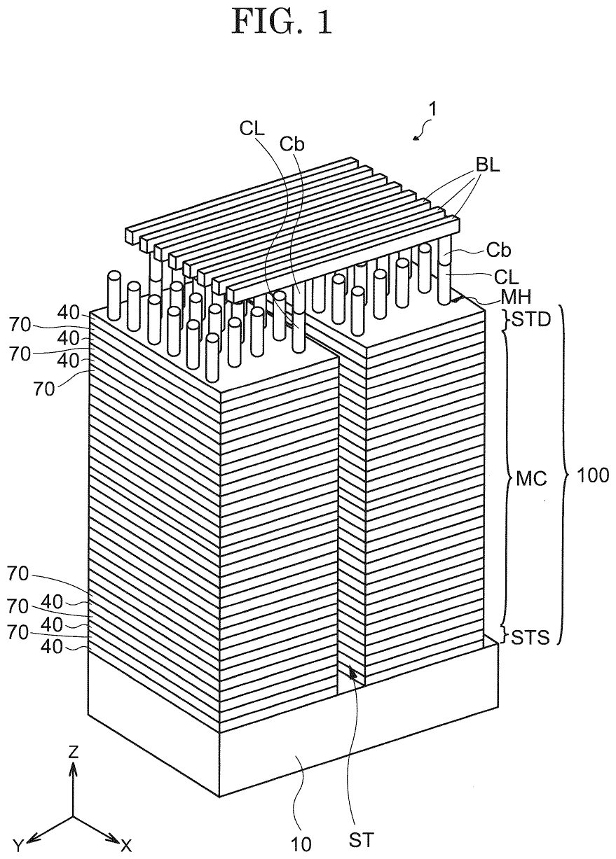

A configuration of a semiconductor device according to the present embodiment will be described with reference to FIG. 1. FIG. 1 is a schematic perspective view showing an arrangement of each element of a semiconductor device 1 according to the present embodiment.

In FIG. 1, two directions parallel to a main surface of a substrate 10 and orthogonal to each other are referred to as an X direction and a Y direction, and a plane parallel to the main surface of the substrate 10 is referred to as a XY plane. A direction orthogonal to both the X direction and the Y direction is referred to as a Z direction (stacking direction).

As shown in FIG. 1, the semiconductor device 1 includes the substrate 10, a laminated body 100 arranged on the substrate 10, a plurality of columnar members CL, and a plurality of bit lines BL arranged on the laminated body 100.

The substrate 10 is, for example, a semiconductor substrate made of P-type silicon (Si) containing a P-type impurity such as boron (B). On a surface of the substrate 10, for example, a P-type well region containing the P-type impurity is arranged.

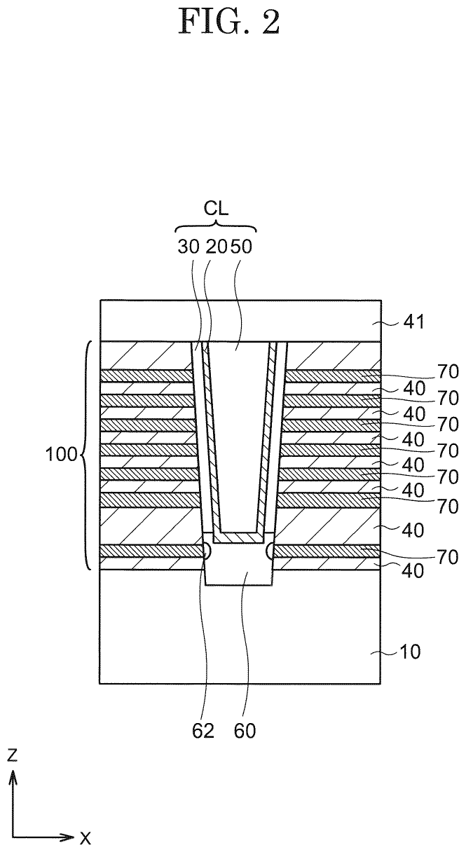

In the laminated body 100, a plurality of conductive layers 70 insulated from each other and openings ST and MH common to the plurality of conductive layers 70 are formed. The openings ST and MH extend in the stacking direction (Z direction), pass through the laminated body 100, and penetrate the laminated body 100 to reach the substrate 10. The opening ST extends in the X direction and separates the laminated body 100 into a plurality of blocks in the Y direction. As will be described later, the columnar members CL are formed in the opening MH (see FIG. 2).

The columnar members CL are formed as cylinders extending in the lamination direction in the laminated body 100. The plurality of columnar members CL are staggered, for example. Alternatively, the plurality of columnar members CL may be arranged in a square grid along the X direction and the Y direction.

The plurality of bit lines BL are separated from each other in the X direction, and each of the bit lines BL extends in the Y direction.

An upper end of the columnar member CL on the semiconducting layer 20 described later (see FIG. 2) is connected to the bit line BL via a contact part Cb. The plurality of columnar members CL selected one by one from the respective blocks separated in the Y direction by the opening ST are connected to a common single bit line BL. Although an insulating layer 40 is formed in the opening ST and an insulating layer 41 is formed on the laminated body 100 (FIG. 2), these insulating layers are omitted in FIG. 1 for convenience of explanation.

FIG. 2 is a schematic cross-sectional view of the semiconductor device 1. The X direction and the Z direction shown in FIG. 2 correspond to the X direction and the Z direction shown in FIG. 1.

The laminated body 100 includes the plurality of conductive layers 70 stacked on the substrate 10. The plurality of conductive layers 70 are periodically stacked in a direction perpendicular to the main surface of the substrate 10 (stacking direction) via the plurality of insulating layers 40. Each of the conductive layers 70 is a single layer. That is, in the case where a cross-sectional shape of one conductive layer 70 is observed, a single material may be continuous in the film thickness direction (Z direction) of the conductive layer 70. In addition, there may be no interface inside one conductive layer 70. A material of the conductive layer 70 may be, for example, tungsten.

The insulating layer 40 is formed between conductive layers 70 adjacent to each other in the stacking direction. The plurality of conductive layers 70 and the plurality of insulating layers 40 are arranged alternately one by one. The insulating layer 40 is also formed between the substrate 10 and the lowermost conductive layer 70. The insulating layer 40 is also formed on the uppermost conductive layer 70. The insulating layer 41 is arranged on the uppermost insulating layer 40. The conductive layers 70 may be insulated from each other, and the insulating layers 40 may be made of silicon oxide such as silicon dioxide (SiO₂), TEOS (Tetra Ethyl Ortho Silicate), or the like. The insulating layers 40 are deposited using, for example, a CVD (Chemical Vapor Deposition) device.

The columnar member CL is formed in the opening MH. The columnar member CL includes an epitaxially grown layer 60, a memory layer 30, the semiconductor layer 20, and an insulating core layer 50. The columnar member CL includes the epitaxially grown layer 60 in a vicinity of the substrate 10. The epitaxial growth layer 60 is formed, for example, by epitaxially growing a silicon single crystal on the substrate 10 containing a silicon single crystal.

The epitaxial growth layer 60 includes an insulating layer 62 at a connection portion with the conductive layer 70. The insulating layer 62 is formed by, for example, oxidizing the epitaxial growth layer 60.

On the epitaxial growth layer 60, the memory layer 30, the semiconductor layer 20, and the insulating core layer 50 extending in the stacking direction (Z direction) are formed. The core layer 50 is arranged in a columnar shape in a vicinity of a center of the opening MH. The semiconductor layer 20 is arranged in a bottomed cylindrical shape around the core layer 50. A lower end of the semiconductor layer 20 is connected to the epitaxial growth layer 60. The memory layer 30 is arranged in a cylindrical shape around the semiconductor layer 20. The memory layer 30 is in contact with an inner surface of the opening MH (the conductive layer 70 and the insulating layer 40 which are alternately stacked). The memory layer 30 is in contact with the semiconductor layer 20. In other words, the semiconductor layer 20 penetrates the laminated body 100. The memory layer 30 (including an electric storage layer 32 described later) is arranged between the conductive layer 70 and the semiconductor layer 20.

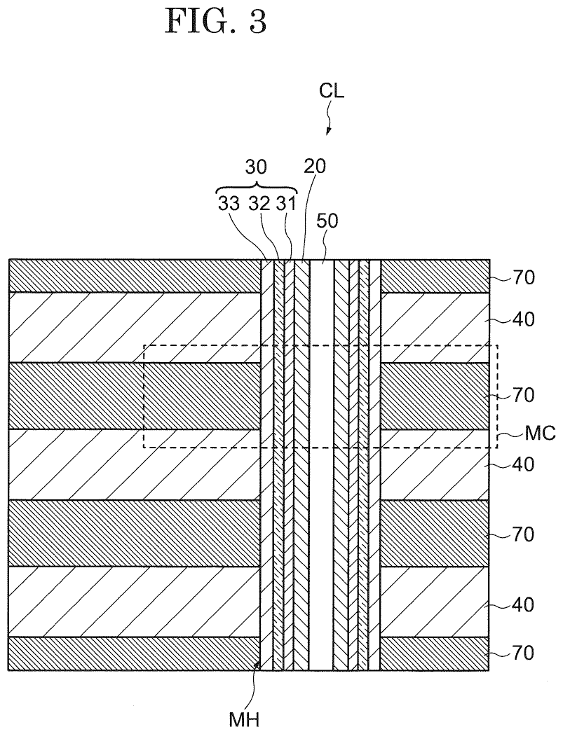

FIG. 3 is an enlarged cross-sectional view of a part of FIG. 2. The columnar member CL is a structure having the memory layer 30, the semiconductor layer 20, and the insulating core layer 50. The semiconductor layer 20 extends continuously in the stacking direction (Z direction) in the laminated body 100. A material of the semiconductor layer 20 includes, for example, amorphous or polycrystalline silicon. The core layer 50 is arranged inside the cylindrical semiconductor layer 20. A material of the core layer 50 includes, for example, silicon oxide. The memory layer 30 is arranged between the conductive layer 70 and the semiconductor layer 20. The memory layer 30 surrounds the semiconductor layer 20 from an outer peripheral side of the semiconductor layer 20.

The memory layer 30 includes a tunnel insulating layer 31, the electric storage layer 32, and a block insulating layer 33 (here, when the tunnel insulating layer 31, the electric storage layer 32, and the block insulating layer 33 are not distinguished from each other, they are referred to as the memory layer 30). The block insulating layer 33, the electric storage layer 32, and the tunnel insulating layer 31 extend continuously in the stacking direction of the laminated body 100 together with the semiconductor layer 20. The block insulating layer 33, the electric storage layer 32, and the tunnel insulating layer 31 are arranged in this order from the conductive layer 70 side between the conductive layer 70 and the semiconductor layer 20. The tunnel insulating layer 31 is in contact with the semiconductor layer 20. The block insulating layer 33 is in contact with the conductive layer 70. The electric storage layer 32 is arranged between the block insulating layer 33 and the tunnel insulating layer 31.

The semiconductor layer 20, the memory layer 30, and the conductive layer 70 constitute a memory cell MC. In FIG. 3, one memory cell MC is schematically represented by a broken line. The memory cell MC has a vertical transistor configuration in which the conductive layer 70 surrounds the semiconductor layer 20 via the memory layer 30.

In the vertical transistor structure memory cell MC, the semiconductor layer 20 functions as a channel and the conductive layer 70 functions as a control gate. The electric storage layer 32 functions as a data layer that stores charges injected from the semiconductor layer 20.

As described above, a plurality of memory cells MC are arranged in the stacking direction of the plurality of conductive layers 70, and the plurality of conductive layers 70 are respectively connected to the plurality of memory cells MC. The conductive layer 70 in a vicinity of the block insulating layer 33 functions as a control gate. Writing or erasing to or from the memory cell MC can be controlled by controlling a voltage applied to the conductive layer 70 connected to the memory cell MC.

The semiconductor device according to the embodiment is a non-volatile semiconductor device capable of electrically freely writing or erasing data to or from a memory cell MC and holding content even if the power supply is turned off.

The memory cell MC is, for example, a charge-trap type memory cell. The electric storage layer 32 has a large number of trap sites for trapping charges in the insulating layer. A material of the electric storage layer 32 includes, for example, silicon nitride.

The tunnel insulating layer 31 serves as a potential barrier when charges are injected from the semiconductor layer 20 into the electric storage layer 32 or when charges stored in the electric storage layer 32 diffuse toward the semiconductor layer 20. A material of the tunnel insulating layer 31 includes, for example, silicon oxide.

The block insulating layer 33 prevents the charge stored in the electric storage layer 32 from diffusing into the conductive layer 70. A material of the block insulating layer 33 includes, for example, silicon oxide.

As shown in FIG. 1, a source-side selection transistor STS is arranged in lower layers of the laminated body 100. A drain-side selection transistor STD is arranged in upper layers of the laminated body 100. For example, the lowermost conductive layer 70 functions as a control gate of the source-side select transistor STS. For example, the uppermost conductive layer 70 functions as a control gate of the drain-side select transistor STD. The plurality of memory cells MC are arranged between the source-side selection transistor STS and the drain-side selection transistor STD.

The plurality of memory cells MC is arranged between the drain-side selection transistor STD and the source-side selection transistor STS. The plurality of memory cells MC, the drain-side selection transistor STD, and the source-side selection transistor STS are connected in series through the semiconductor layer 20 to form one memory string. The memory strings are, for example, staggered in a plane direction parallel to the XY plane, and the plurality of memory cells MC is three-dimensionally arranged in the X direction, the Y direction, and the Z direction.

### [Method for Manufacturing Semiconductor Device]

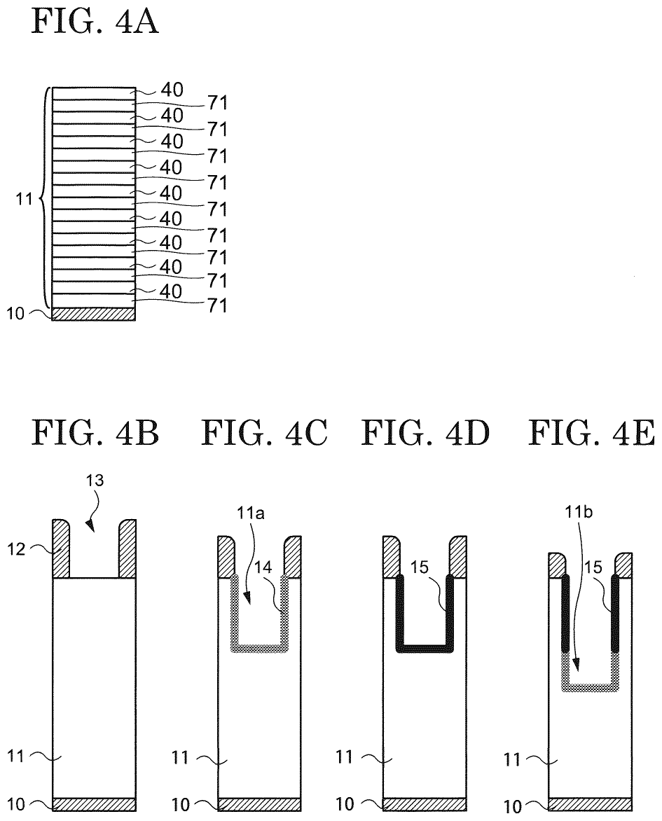

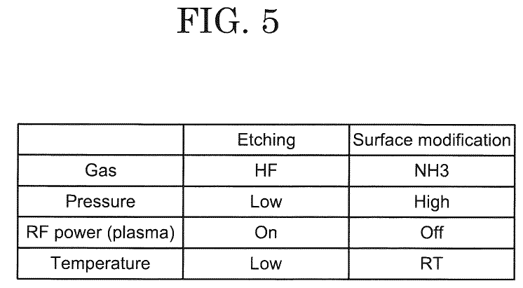

Next, referring to FIG. 4A to FIG. 4E and FIG. 5, a method for manufacturing the semiconductor device 1 of the first embodiment will be described. FIG. 4A to FIG. 4E are cross-sectional views showing the method for manufacturing the semiconductor device according to the present embodiment. FIG. 5 is a diagram showing the method for manufacturing the semiconductor device according to the present embodiment.

As shown in FIG. 4A, first, the insulating layer 40 (TEOS film) and a sacrificing layer 71 (SiN film) are alternately formed on the substrate 10 to form a laminated body 11. The insulating layer 40 and the sacrificing layer 71 are deposited using, for example, a CVD device. The plurality of insulating layers 40 and a plurality of sacrificing layers 71 which are alternately stacked are formed so as to be in contact with each other. Although silicon dioxide (SiO₂) is exemplified as the material of the insulating layer 40 in the present embodiment, the material of the insulating layer 40 is not limited to this, and may be, for example, a TEOS film. In the present embodiment, although the material of the sacrificing layer 71 is a silicon nitride film (SiN), the material of the sacrificing layer 71 is not limited thereto, and may be, for example, silicon. In the following description, when the insulating layer 40 and the sacrificing layer 71 are not distinguished from each other, the laminated structure is omitted and is described as the laminated body 11.

Next, as shown in the FIG. 4B, the mask 12 having a pattern of memory holes MH is formed on an upper surface of the laminated body 11 (a surface facing away from the substrate 10). The mask 12 is preferably a hard mask, and a material of the mask 12 may be, for example, carbon. The material of the mask 12 may include two or more materials having different compositions, and in this case, the mask 12 may have a laminated structure including two or more layers including materials having different compositions. The mask 12 is deposited using, for example, a CVD device. The pattern of the mask 12 is formed by dry etching using an intermediate layer (not shown) such as a silicon oxide film formed between the mask 12 and a resist using a resist mask formed by photolithography of the resist. The pattern of the mask 12 has an opening pattern 13 that exposes a surface of the laminated body 11 (insulating layer 40) in a region where the memory hole MH is to be formed.

Next, as shown in FIG. 4C, plasma etching (hereinafter, also referred to as “Etching”) is performed using a gas containing hydrogen fluoride (HF). For example, the laminated body 11 may be etched by a dry etching technique using a hydrogen fluoride/phosphorus trifluoride (HF/PF₃) mixed gas plasma. The plurality of insulating layers 40 and the plurality of sacrificing layers 71 are etched by plasma etching to form a recess 11a in a region of the laminated body 11 exposed by the opening pattern 13 of the mask 12. At this time, a modified layer 14 is formed on the insulating layer 40 (for example, silicon dioxide (SiO₂)) exposed in the recess 11a of the laminated body 11. The modified layer 14 includes fluorine (F) and hydrogen (H). In addition, in FIG. 4C, the modified layer 14 is selectively formed on a surface of silicon oxide as the insulating layer 40, and is hardly formed on a surface of silicon nitride as the sacrificing layer 71 exposed in the recess 11a. An example of forming the modified layer 14 on the surface of the silicon nitride will be described later.

RF power, RF frequency, and the like for plasma generation during plasma etching are not particularly limited. Capacitively coupled plasma that superimpose two or more frequencies of RF are preferably used. For example, a range of RF frequency on a high frequency side is preferably 50 MHz or more and 100 MHz or less, a range of RF frequency on a low frequency side is preferably 0.1 MHz or more and 5 MHz or less, a range of input power is preferably several kW or several tens of kW or more, and higher power may be applied in accordance with the aspect ratio of a workpiece. A range of pressure is preferably 10 mT or more and 50 mT or less, and a range of temperature of a substrate stage is preferably controlled to be, for example, −10° C. or lower and −50° C. or higher. In addition, since the substrate being etched receives heat input from the plasma, the temperature of the substrate is, for example, several tens of degrees Celsius higher than the temperature of the stage. An etching rate of the laminated body 11 can be improved by lowering the temperature of the substrate during etching using hydrogen fluoride (HF) plasma. In the present embodiment, the temperature of the substrate is, for example, about 20° C.

Subsequently, the etching is stopped prior to a diameter of the recess 11a exceeding an allowable dimension. Supply of the gas and application of the high frequency power are stopped (turning off the plasma) while the substrate is left on the stage, and vacuum drawing is performed. However, the present disclosure is not limited thereto, and may be omitted as long as switching of the gas, the temperature, and the like can be performed instantaneously. On the other hand, an inert gas such as argon (Ar) may be purged to reliably eliminate effects of residual gas.

Next, as shown in FIG. 4D, a protective layer 15 containing nitrogen, hydrogen, and fluorine is formed by supplying a gas containing nitrogen and hydrogen (for example, molecular hydrogen nitride) (hereinafter, also referred to as “Surface modification”). For example, ammonia (NH₃) gas, which is a gas containing nitrogen and hydrogen, is introduced without applying a high frequency power, and the substrate is exposed to an ammonia (NH₃) atmosphere. In this case, the modified layer 14 formed by HF plasma and HF gas becomes the protective layer 15 containing nitrogen/hydrogen and fluorine. The protective layers 15 may include ammonium hexafluorosilicate ((NH₄)₂SiF₆).

Here, at the time of forming the protective layer 15, it is preferable to raise the temperature of the substrate stage to, for example, about 25° C. by a chiller to set the temperature of the substrate to about room temperature. The temperature at the time of forming the protective layer 15 is preferably higher than the temperature at the time of etching. In addition, in order to accelerate a formation reaction of the protective layer 15 containing ammonium hexafluorosilicate ((NH₄)₂SiF₆), pressure at the time of introducing the ammonia (NH₃) gas is preferably increased to about 500 mT. For example, the pressure at the time of introduction of ammonia (NH₃) gas is preferably 100 mT or more. For example, the pressure at the time of introduction of ammonia (NH₃) gas is preferably 500 mT or more. That is, pressure at the time of forming the protective layer 15 is preferably at least one order of magnitude higher than pressure at the time of etching. FIG. 5 shows relationships among types of gas, pressure, plasma, and temperature at the time of etching and the formation of the protective layer 15.

In the present embodiment, the application of the high frequency power is stopped (turning off the plasma) at the time of the introduction of the ammonia (NH₃) gas. Since plasma formation requires power, energy and cost can be reduced by stopping the application of the high frequency power (turning off the plasma). Further, by stopping the application of the high frequency power (turning off the plasma), it is possible to suppress generation of various active species caused by converting ammonia (NH₃) into plasma. It is possible to avoid problems such as the active species reacting with the substrate or a surface of a vacuum chamber to form unwanted reaction products, which then cause particles to be generated in the chamber by suppressing the generation of active species.

After that, the supply of the ammonia (NH₃) gas is stopped, and vacuum drawing is performed. However, the present disclosure is not limited thereto, and may be omitted as long as switching of the gas, the temperature, and the like can be reliably performed. On the other hand, an inert gas such as argon (Ar) may be purged to reliably eliminate effects of residual gas.

Next, as shown in FIG. 4E, plasma etching is resumed using a gas containing hydrofluoric acid (HF). Conditions for the plasma etching may be the same as described above. The protective layers 15 are removed from a bottom surface of the recess 11a that receives normal incidence of ions by the plasma etching, and etching of a recess 11b proceeds. The protective layer 15 on the side surfaces of the recess 11a remain, and lateral etching due to obliquely incident ions can be suppressed. It is possible to prevent adjacent patterns from coming into contact with each other and collapsing by suppressing the lateral etching (enlargement of a pattern dimension). That is, the bottom surface of the recess 11a can be lowered to form the recess 11b having a higher aspect ratio. In this case, the modified layer 14 is formed on a side surface and a bottom surface of the recess 11b without the protective layer 15.

Thereafter, in the case where the recess 11b reaches a desired depth of the memory hole MH, the plasma etching is terminated. If the recess 11b does not reach the desired depth of the memory hole MH, the formation of the protective layer 15 shown in FIG. 4D and the plasma etching and the formation of modified layer 14 shown in FIG. 4E are repeated until the recess 11b reaches the desired depth of the etching.

After the recess reaches the desired depth of the memory hole MH, ashing is performed at 200° C. or more and 300° C. or less in order to remove the mask 12. The protective layers 15 remaining on the side surfaces of the recess 11a can also be removed by heating to 100° C. or more.

A method for forming the columnar member CL is not particularly limited. The columnar member CL can be formed by using conventional methods. Further, the sacrificing layer 71 is removed by an etchant after the columnar member CL is formed, and the conductive layer 70 is formed, whereby the semiconductor device 1 shown in FIG. 2 can be manufactured.

As described above, according to the method for manufacturing the semiconductor device of the present embodiment, the etching with a high aspect ratio in which the enlargement of the pattern dimension is suppressed can be performed by performing second and subsequent plasma etching after the protective layer 15 is formed, and a memory hole MH with a high aspect ratio can be formed. Therefore, reliability and manufacturing yield of the semiconductor device can be improved.

Although the present embodiment exemplifies the method for forming the memory hole MH, the disclosed technique is not limited thereto, and can be applied to forming any pattern such as a contact hole, a line pattern, or a square pad pattern. Alternatively, a single layer of silicon oxide may be used instead of the laminated body 11.

### Modification 1

In FIG. 4C, an example in which the modified layer 14 is formed on the recess 11a of the laminated body 11 by plasma etching using the gas containing hydrofluoric acid (HF) was shown. However, in order to more reliably form the modified layer 14, the application of the high frequency power may be stopped (turning off the plasma) and the gas containing hydrogen fluoride (HF) may be supplied to perform surface treatment after the plasma etching and prior to the formation of the protective layer 15. In order to accelerate the formation reaction of the modified layer 14, the temperature at the time of formation of the modified layer 14 is preferably higher than the temperature at the time of etching, and pressure at the time of formation of the modified layer 14 is preferably one order of magnitude higher than pressure at the time of etching.

### Modification 2

More specifically, in FIG. 4C, an example in which plasma etching using a hydrogen fluoride/phosphorus trifluoride (HF/PF₃) mixed gas was shown. However, at least one of phosphorus trichloride (PCl₃), phosphorus pentafluoride (PF₅), boron trifluoride (BF₃), water (H₂O), and various alcohols may be further added to promote surface adsorption of hydrogen fluoride (HF). At least one of carbon tetrafluoride (CF₄), trifluoromethane (CHF₃), difluoromethane (CH₂F₂), fluoromethane (CH₃F), octafluorocyclobutane (C₄F₈), hexafluoro 1, 3 butadiene (C₄F₆), hydrogen bromide (HBr), trifluoromethane (CF₃I), and iodine seven fluoride (IF₇) may be further added for the purpose of shape controlling a low aspect ratio portion. At least one of sulfur hexafluoride (SF₆), nitrogen trifluoride (NF₃), fluorine (F₂), and xenon difluoride (XeF₂) may be further added to supplement fluorine supply. At least one of chlorine (Cl₂), hydrochloric acid (HCl), and boron trichloride (BCI₃), which control a shape of a high aspect ratio portion, may be further added.

### Modification 3

In FIG. 4C, an example in which the plasma etch using the hydrogen fluoride/phosphorus trifluoride (HF/PF₃) mixed gas plasma was shown. However, it is also possible to use mixed gas plasma which generates hydrofluoric acid (HF) in the plasma. For example, hydrogen fluoride (HF) can be produced in gas phase or on a wafer surface by mixing a gas containing fluorine (NF₃, SF₆, a fluorocarbon-based gas in general, or the like) and a gas containing hydrogen (H₂, H₂O, or the like), such as a carbon tetrafluoride/hydrogen (CF₄/H₂) mixed gas, nitrogen trifluoride/hydrogen (NF₃/H₂), sulfur hexafluoride/hydrogen (SF₆/H₂), or the like.

### Modification 4

In FIG. 4D, an example in which the protective layers 15 are formed using the ammonia (NH₃) gas was shown. However, instead of the ammonia (NH₃) gas, it is also possible to use heavy ammonia (ND₃) gas which is less likely to desorb from the surface after adsorption.

### Second Embodiment

### [Method for Manufacturing Semiconductor Device]

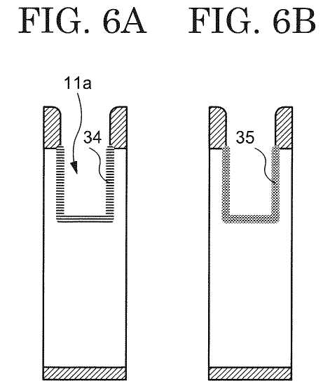

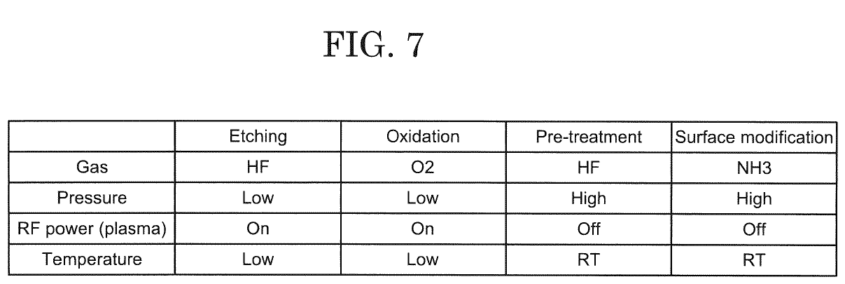

A method for manufacturing the semiconductor device 1 according to a second embodiment of the present disclosure will be described with reference to FIG. 6A, FIG. 6B, and FIG. 7. The semiconductor device 1 according to the second embodiment is the same as the semiconductor device 1 according to the first embodiment. The method for manufacturing the semiconductor device 1 according to the second embodiment is the same as the method for manufacturing the semiconductor device 1 according to the first embodiment except that the oxide layer and the modified layer are formed before a protective layer is formed. In the following description, description of a manufacturing method similar to that of the first embodiment will be omitted, and a manufacturing method different from that of the first embodiment will mainly be described. FIG. 6A and FIG. 6B are cross-sectional views showing the method for manufacturing the semiconductor device according to the present embodiment. FIG. 7 is a diagram showing a method for manufacturing the semiconductor device according to the present embodiment.

First, the laminated body 11 is formed as described with reference to FIG. 4A, the mask 12 is formed as described with reference to FIG. 4B, and the recess 11a is formed by plasma etching using a gas containing hydrogen fluoride (HF) as described with reference to FIG. 4C. In this case, although not shown, the modified layer 14 may be formed on the surface of the silicon oxide as the insulating layer 40.

Next, as shown with reference to FIG. 6A, a silicon oxide layer 34 is selectively formed on the sacrificing layer 71 (for example, a silicon nitride film (SiN)) exposed in the recess 11a of the laminated body 11 by performing plasma treatment using an oxygen gas (hereinafter, also referred to as “Oxidation”). As conditions of the oxygen gas plasma, it is preferable to perform short-time treatment with power of about 1/10 of the power at the time of etching so as to minimize consumption of the mask 12.

Next, as shown in FIG. 6B, the application of the high frequency power is stopped (turning off the plasma) and the surface treatment is performed with the gas containing hydrogen fluoride (HF) after the plasma treatment, thereby forming a modified layer 35 (hereinafter, also referred to as “Pre-treatment”). The modified layer 35 is formed on surfaces of the silicon oxide layer 34 and the insulating layer 40 exposed in the recess 11a of the laminated body 11. The modified layer 35 may contain fluorine (F) or hydrogen (H). In order to accelerate formation reaction of the modified layer 35, the temperature at the time of formation of the modified layer 35 is preferably higher than the temperature at the time of etching and the temperature at the time of formation of the silicon oxide layer 34, and pressure at the time of formation of the modified layer 35 is preferably one order of magnitude higher than pressure at the time of etching and pressure at the time of formation of the silicon oxide layer 34. FIG. 7 shows relationships among types of gas, pressure, plasma, and temperature at the time of etching, the time of forming the silicon oxide layer 34, the time of forming the modified layer 35, and the time of forming the protective layer 15.

Next, the protective layer 15 is formed as described in FIG. 4D, and the plasma etching is resumed using the gas containing hydrofluoric acid (HF) as described in FIG. 4E.

In the present embodiment, the silicon oxide layer 34 is formed on a surface of the sacrificing layer 71 by performing plasma treatment using the oxygen gas. Therefore, the modified layer 35 can be formed on both the silicon oxide layer 34 and the insulating layer 40 exposed in the recess 11a of the laminated body 11, and the protective layer 15 can be formed over a wider area. The protective layer 15 on the side surface of the recess 11a can suppress lateral etching due to obliquely incident ions. It is possible to prevent adjacent patterns from coming into contact with each other and collapsing by suppressing the lateral etching (enlargement of the pattern dimension). That is, the bottom surface of the recess 11a can be lowered to form the recess 11b having a higher aspect ratio. In this case, the modified layer 14 is formed on the side surface and the bottom surface of the recess 11b without the protective layer 15.

Thereafter, in the case where the recess 11b reaches a desired depth of the memory hole MH, the plasma etching is terminated. If the recess 11b does not reach the desired depth of the memory hole MH, the formation of the silicon oxide layer 34 shown in FIG. 6A, the formation of the modified layer 35 shown in FIG. 6B, the formation of the protective layer 15 shown in FIG. 4D, and the plasma etching shown in FIG. 4E are repeated until the recess 11b reaches the desired depth of etching.

As described above, according to the method for manufacturing a semiconductor device of the present embodiment, second and subsequent plasma etching after the protective layer 15 is formed enables etching with a high aspect ratio in which the enlargement of the pattern dimension is suppressed, and thus it is possible to form a memory hole MH with a high aspect ratio. Therefore, reliability and manufacturing yield of the semiconductor device can be improved.

Although the present embodiment exemplifies the method for forming the memory hole MH, the disclosed technique is not limited thereto, and can be applied to forming any pattern such as a contact hole, a line pattern, or a square pad pattern. Alternatively, a single layer of silicon nitride may be used instead of the laminated body 11.

### Third Embodiment

### [Method for Manufacturing Semiconductor Device]

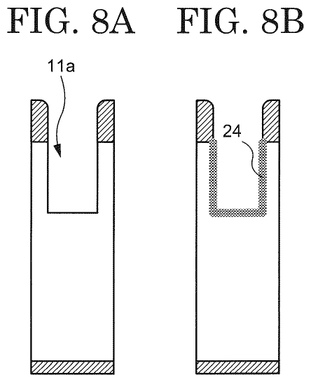

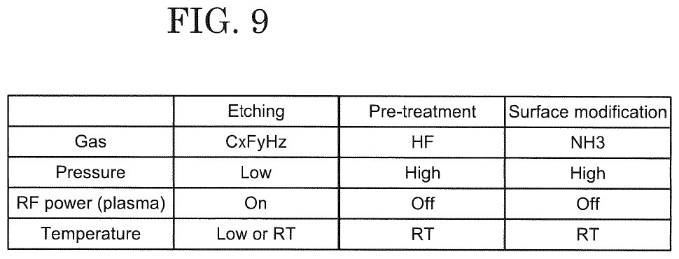

A method for manufacturing the semiconductor device 1 according to a third embodiment of the present disclosure will be described with reference to FIG. 8A, FIG. 8B, and FIG. 9. The semiconductor device 1 according to the third embodiment is the same as the semiconductor device 1 according to the first embodiment. The method for manufacturing the semiconductor device 1 according to the third embodiment is the same as the method for manufacturing the semiconductor device 1 according to the first embodiment except for the etching method and forming the modified layer before the protective layer is formed. In the following description, description of a manufacturing method similar to that of the first embodiment will be omitted, and a manufacturing method different from that of the first embodiment will mainly be described. FIG. 8A and FIG. 8B are cross-sectional views showing the method for manufacturing the semiconductor device according to the present embodiment. FIG. 9 is a diagram showing the method for manufacturing the semiconductor device according to the present embodiment.

First, the laminated body 11 is formed as described in FIG. 4A, and the mask 12 is formed as described in FIG. 4B.

Next, as shown in FIG. 8A, plasma etching (Etching) is performed using a fluorocarbon gas containing fluorine and carbon or a hydrofluorocarbon gas containing fluorine, carbon and hydrogen. For example, the laminated body 11 may be etched by a dry etching technique using hexafluoro 1,3 butadiene/oxygen/argon (C₄F₆/O₂/Ar) mixed gas plasma or trifluoromethane/oxygen/argon (CHF₃/O₂/Ar) mixed gas plasma. The recess 11a is formed in a region of the laminated body 11 exposed by the opening pattern 13 of the mask 12 by performing plasma etching.

RF power and RF frequency are not particularly limited. Capacitively coupled plasma that superimpose and apply two or more frequencies of RF are preferably used. For example, a range of RF frequency on a high frequency side is preferably 50 MHz or more and 100 MHz or less, a range of RF frequency on a low frequency side is preferably 0.1 MHz or more and 5 MHz or less, and a range of input power is preferably several kW or more and several tens of kW or less. A range of pressure is preferably 10 mT or more and 50 mT or less, and a range of temperature of the substrate stage is preferably about 25° C. For example, when the trifluoromethane/oxygen/argon (CHF₃/O₂/Ar) mixed gas plasma is used, the substrate stage is preferably etched by controlling the temperature to −10° C. or lower and −50° C. or higher.

Subsequently, the etching is stopped prior to a diameter of the recess 11a exceeding an allowable dimension. Supply of the gas and application of the high frequency power are stopped (turning off the plasma) while the substrate is left on the stage, and vacuum drawing is performed. However, the present disclosure is not limited thereto, and may be omitted as long as switching of gas, temperature, and the like can be performed. On the other hand, an inert gas such as argon (Ar) may be purged to reliably eliminate effects of residual gas.

Next, as shown in FIG. 8B, the application of the high frequency power is stopped (turning off the plasma) to perform surface treatment with the gas containing hydrogen fluoride (HF) after the plasma etching, thereby forming a modified layer 24 (Pre-treatment). The modified layer 24 is formed on the insulating layer 40 (for example, silicon dioxide (SiO₂)) exposed in the recess 11a of the laminated body 11. The modified layer 24 may contain fluorine (F) or hydrogen (H). In order to accelerate formation reaction of the modified layer 24, the temperature at the time of formation of the modified layer 24 is preferably higher than the temperature at the time of etching, and pressure at the time of formation of the modified layer 24 is preferably one order of magnitude higher than pressure at the time of etching. In addition, in FIG. 8B, the modified layer 24 is selectively formed on a surface of silicon oxide as the insulating layer 40, and is hardly formed on a surface of silicon nitride as the sacrificing layer 71 exposed in the recess 11a. FIG. 9 shows relationships among types of gas, pressure, plasma, and temperature at the time of etching, formation of the modified layer 24, and formation of the protective layer 15.

Next, the protective layer 15 is formed as described in FIG. 4D, and the plasma etching is resumed using the fluorocarbon gas or the hydrofluorocarbon gas as described in FIG. 8A. Conditions for the plasma etching may be the same as described above. The protective layer 15 is removed from the bottom surface of the recess 11a that receives the normal incidence of the ions by the plasma etching, and the etching of the recess 11b proceeds.

In the present embodiment, the protective layers 15 on the side surface of the recess 11a can suppress lateral etch due to obliquely incident ions. It is possible to prevent adjacent patterns from coming into contact with each other and collapsing by suppressing the lateral etching (enlargement of the pattern dimension). That is, the bottom surface of the recess 11a can be lowered to form the recess 11b having a higher aspect ratio.

Thereafter, in the case where the recess 11b reaches a desired depth of the memory hole MH, the plasma etching is terminated. In the case where the recess 11b has not reached the desired depth of the memory hole MH, the formation of the modified layer 24 shown in FIG. 8B, the formation of the protective layer 15 shown in FIG. 4D, and the plasma etching shown in FIG. 8A are repeated until the recess 11b reaches the desired depth of etching.

As described above, according to the method for manufacturing the semiconductor device of the present embodiment, the second and subsequent plasma etching after the protective layer 15 is formed enables etching with a high aspect ratio in which the enlargement of the pattern dimension is suppressed, and thus it is possible to form the memory hole MH with a high aspect ratio. Therefore, reliability and manufacturing yield of the semiconductor device can be improved.

Although the present embodiment exemplifies the method for forming the memory hole MH, the disclosed technique is not limited thereto, and can be applied to forming any pattern such as a contact hole, a line pattern, or a square pad pattern. Alternatively, a single layer of silicon oxide may be used instead of the laminated body 11.

### Fourth Embodiment

### [Method for Manufacturing Semiconductor Device]

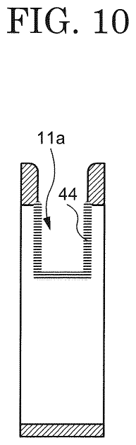

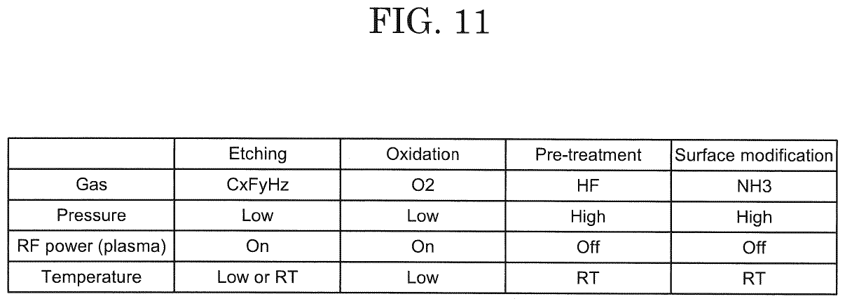

A method for manufacturing the semiconductor device 1 according to the fourth embodiment will be described with reference to FIG. 10 and FIG. 11. The semiconductor device 1 according to the fourth embodiment is the same as the semiconductor device 1 according to the first embodiment. The method for manufacturing the semiconductor device 1 according to the fourth embodiment is the same as the method for manufacturing the semiconductor device 1 according to the third embodiment except that the oxide layer is formed before forming the modified layer. In the following description, the same manufacturing methods as those of the first and third embodiments will be omitted, and manufacturing methods different from those of the first and third embodiments will mainly be described. FIG. 10 is a cross-sectional view showing the method for manufacturing the semiconductor device according to the present embodiment. FIG. 11 is a diagram showing the method for manufacturing the semiconductor device according to the present embodiment.

First, the laminated body 11 is formed as described with reference to FIG. 4A, the mask 12 is formed as described with reference to FIG. 4B, and the recess 11a is formed by plasma etching using the fluorocarbon gas or the hydrofluorocarbon gas as described with reference to FIG. 8A.

Next, as shown in FIG. 10, a silicon oxide layer 44 is formed on the sacrificing layer 71 (for example, a silicon nitride film (SiN)) exposed in the recess 11a of the laminated body 11 by performing plasma treatment using the oxygen gas (Oxidation). As conditions of the oxygen gas plasma, it is preferable to perform short-time treatment with power of about 1/10 of the power at the time of etching so as to minimize consumption of the mask 12.

Next, as shown in FIG. 8B, the application of the high frequency power is stopped (turning off the plasma), and surface treatment is performed with the gas containing hydrogen fluoride (HF) after the plasma treatment, thereby forming the modified layer 24 (Pre-treatment). The modified layer 24 is formed on surfaces of the silicon oxide layer 44 and the insulating layer 40 exposed in the recess 11a of the laminated body 11. The modified layer 24 may contain fluorine (F) or hydrogen (H). In order to accelerate formation reaction of the modified layer 24, the temperature at the time of formation of the modified layer 24 is preferably higher than the temperature at the time of etching and at the time of formation of the silicon oxide layer 44, and pressure at the time of formation of the modified layer 24 is preferably one order of magnitude higher than pressure at the time of etching and at the time of formation of the silicon oxide layer 44. FIG. 11 shows relationships among types of gas, pressures, plasma, and temperatures at the time of etching, the time of forming the silicon oxide layer 44, the time of forming the modified layer 24, and the time of forming the protective layer 15.

Next, the protective layers 15 are formed as described in FIG. 4D, and plasma etching is resumed using the fluorocarbon gas or a gas containing the hydrofluorocarbon gas as described in FIG. 8A. Conditions for the plasma etching may be the same as described above. The protective layer 15 is removed from the bottom surface of the recess 11a that receives the normal incidence of the ions by the plasma etching, and the etching of the recess 11b proceeds.

In the present embodiment, the silicon oxide layer 44 is formed on the surface of the sacrificing layer 71 by performing plasma treatment using the oxygen gas. Therefore, the modified layer 24 can be formed on both the silicon oxide layer 44 and the insulating layer 40 exposed in the recess 11a of the laminated body 11, and can be formed on the protective layer 15 in a wider area. The protective layer 15 on the side surface of the recess 11a can suppress lateral etch due to obliquely incident ions. It is possible to prevent adjacent patterns from coming into contact with each other and collapsing by suppressing the lateral etching (enlargement of the pattern dimension). That is, the bottom surface of the recess 11a can be lowered to form the recess 11b having a higher aspect ratio.

Thereafter, in the case where the recess 11b reaches a desired depth of the memory hole MH, the plasma etching is terminated. In the case where the recess 11b has not reached the desired depth of the memory hole MH, the formation of the silicon oxide layer 44 shown in FIG. 10, the formation of the modified layer 24 shown in FIG. 8B, the formation of the protective layer 15 shown in FIG. 4D, and the plasma etching shown in FIG. 8A are repeated until the recess 11b reaches the desired etch depth.

As described above, according to the method for manufacturing the semiconductor device of the present embodiment, the second and subsequent plasma etching after the protective layer 15 is formed enables etching with a high aspect ratio in which the enlargement of the pattern dimension is suppressed, and thus it is possible to form the memory hole MH with a high aspect ratio. Therefore, reliability and manufacturing yield of the semiconductor device can be improved.

Although the present embodiment exemplifies the method for forming the memory hole MH, the disclosed technique is not limited thereto, and can be applied to forming any pattern such as a contact hole, a line pattern, or a square pad pattern. Alternatively, a single layer of silicon nitride may be used instead of the laminated body 11.

### Fifth Embodiment

### [Configuration Example of Semiconductor Manufacturing Apparatus]

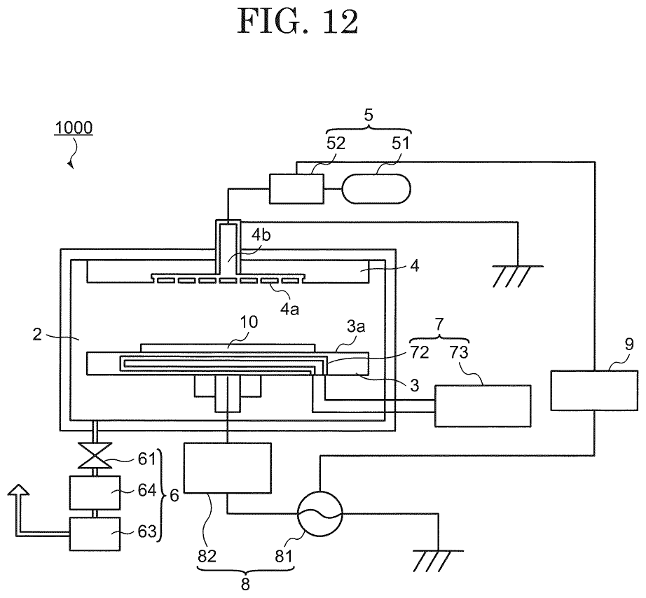

FIG. 12 is a schematic diagram showing a configuration example of a semiconductor manufacturing apparatus that can be used in a semiconductor manufacturing process. A semiconductor manufacturing apparatus 1000 includes a processing chamber 2, an electrode 3, an electrode 4, a gas supplier 5, a gas exhauster 6, a cooling device 7, a power supplier 8, and a control circuit 9.

The processing chamber 2 is a space capable of etching a film to be processed on the substrate 10 by reactive ion etching using plasma, plasma treatment using an oxygen gas (formation of a silicon oxide layer), surface treatment using a gas containing hydrogen fluoride (HF) (formation of a modified layer), and supply of hydrogen nitride molecules (formation of a protective layer). Each process can be performed alternately in the same chamber. In addition, the processing chamber 2 may have a door (gate) for loading and unloading the substrate 10.

The electrode 3 is a lower electrode and has a function as a stage for mounting the substrate 10. The electrode 3 has a front surface 3a that is a mounting surface of the substrate 10. In addition, the semiconductor manufacturing apparatus 1000 may include an electrostatic chuck for holding the substrate 10.

The electrode 4 is an upper electrode. The electrode 4 has a surface 4a and an opening 4b for introducing gas through the electrode 4 into the processing chamber 2. The opening 4b has a plurality of inlets in the surface 4a.

The gas supplier 5 includes a gas supply source 51 such as a cylinder cabinet and a mass flow controller 52. The gas supplier 5 supplies gas from the gas supply source 51 to the processing chamber 2.

The gas source 51 contains a first gas (GAS1), a second gas (GAS2), and a third gas (GAS3). The first gas, the second gas, and the third gas are respectively accommodated in a container such as a gas cylinder.

The first gas includes hydrofluoric acid (HF). The first gas may include, for example, a hydrogen fluoride/phosphorus trifluoride (HF/PF₃) mixed gas. The second gas includes an inert gas such as argon gas. The third gas includes hydrogen nitride molecules. The third gas may include an ammonia (NH₃) gas. The mass flow controller 52 adjusts the flow rate of the first gas and the flow rate of the second gas introduced into the processing chamber 2 from the gas supply source 51.

The gas exhauster 6 includes a valve 61, a turbo molecular pump 64, and a dry pump 63. The gas exhauster 6 has a function of reducing pressure inside the processing chamber 2 to a vacuum state, and also has a function of discharging the gas inside the processing chamber 2.

The cooling device 7 includes, for example, a chiller 73 and a coolant pipe 72 inside the electrode 3. The chiller 73 cools the substrate 10 by circulating refrigerant through the coolant pipe 72. If another chiller is installed and a function of switching the refrigerant is provided, an instantaneous temperature change as in the present embodiment can be efficiently performed.

The power supplier 8 includes a power supply 81 that supplies AC voltage, and a matching circuit 82 such as a matching box. The power supplier 8 has a function of matching impedance between the processing chamber 2 and the power supply 81 by the matching circuit 82 and supplying a high frequency voltage (RF) to the processing chamber 2. The high frequency voltage is, for example, AC voltage having a frequency of 200 kHz or more and 200 MHz or less.

The control circuit 9 controls the mass flow controller 52 and the power supply 81. The control circuit 9 is configured using, for example, hardware using a processor or the like. In addition, each operation may be stored as an operation program in a computer-readable recording medium such as a memory, and each operation may be executed by appropriately reading the operation program stored in the recording medium by hardware.

Although several embodiments have been described above, these embodiments are presented only as examples and are not intended to limit the scope of the disclosure. The novel apparatus and methods described herein can be implemented in various other forms. Moreover, various omissions, substitutions, and changes may be made to the embodiments of the apparatus and methods described herein without departing from the spirit of the disclosure. The accompanying claims and their equivalents are intended to cover such embodiments or modifications as would fall within the scope and spirit of the disclosure.

It is to be understood that other operational effects that are different from the operational effects provided by the aspects of the embodiments described above, and those that can be easily predicted by a person skilled in the art are naturally brought about by the present invention.

What is claimed is:

1. A method for manufacturing a semiconductor device comprising:
preparing a substrate having a film to be processed;
forming a recess on the film to be processed by performing a first etching process by plasma using a gas containing hydrogen fluoride;
forming a first protective layer containing nitrogen, hydrogen, and fluorine by supplying a gas containing nitrogen and hydrogen to the recess without applying high frequency power; and
performing a second etching process to the recess in which the first protective layer is formed thereon by the plasma.

2. The method for manufacturing the semiconductor device according to claim 1 further comprising after the second etching:
forming a second protective layer containing nitrogen, hydrogen and fluorine by supplying a gas containing nitrogen and hydrogen to the recess without applying high frequency power; and
performing a third etching process to the recess in which the second protective layer is formed thereon by the plasma.

3. The method for manufacturing the semiconductor device according to claim 1, wherein the gas containing nitrogen and hydrogen is an ammonia gas or a deuterium ammonia gas.

4. The method for manufacturing the semiconductor device according to claim 1 further comprising after the first etching and before forming the first protective layer:
supplying the gas containing hydrogen fluoride to the recess without applying high frequency power.

5. The method for manufacturing the semiconductor device according to claim 1, wherein a temperature forming the first protective layer is higher than a temperature forming the recess.

6. The method for manufacturing the semiconductor device according to claim 1, wherein pressure forming the first protective layer is higher than pressure forming the recess.

7. The method for manufacturing the semiconductor device according to claim 1 further comprising after the first etching and before forming the first protective layer:
forming an oxide layer on the recess by performing plasma treatment using oxygen gas; and
forming a modified layer containing fluorine and hydrogen by supplying the gas containing hydrogen fluoride to the recess in which the oxide layer has been formed without applying high frequency power.

8. The method for manufacturing the semiconductor device according to claim 7, wherein a temperature forming the modified layer is higher than a temperature forming the recess.

9. The method for manufacturing the semiconductor device according to claim 7, wherein pressure forming the modified layer is higher than pressure forming the recess.

10. The method for manufacturing the semiconductor device according to claim 1, wherein the film to be processed includes a silicon oxide film and a silicon nitride film, and the silicon oxide film and the silicon nitride film are alternately stacked.

11. The method for manufacturing the semiconductor device according to claim 1, wherein forming the recess and forming the first protective layer are performed in the same chamber.

12. A method for manufacturing a semiconductor device comprising:
preparing a substrate having a film to be processed;
forming a recess on the film to be processed by performing a first etching process using plasma containing a fluorocarbon gas or a hydrofluorocarbon gas;
forming a first modified layer containing fluorine and hydrogen by supplying a gas containing hydrogen fluoride to the recess without applying high frequency power;
forming a first protective layer containing nitrogen, hydrogen, and fluorine by supplying a gas containing nitrogen and hydrogen to the recess in which the first modified layer is formed thereon without applying high frequency power; and
performing a second etching process using the plasma to the recess in which the first protective layer is formed thereon.

13. The method for manufacturing the semiconductor device according to claim 12 further comprising after the second etching:
forming a second modified layer containing fluorine by supplying a gas containing hydrogen fluoride in the recess without applying high frequency power;
forming a second protective layer containing nitrogen, hydrogen and fluorine by supplying a gas containing nitrogen and hydrogen to the recess in which the second modified layer is formed thereon without applying high frequency power; and
performing a third etching process to the recess in which the second protective layer is formed therein by the plasma.

14. The method for manufacturing the semiconductor device according to claim 12, wherein the gas containing nitrogen and hydrogen is ammonia gas or deuterium ammonia gas.

15. The method for manufacturing the semiconductor device according to claim 12, wherein a temperature forming the first protective layer is higher than a temperature forming the recess.

16. The method for manufacturing the semiconductor device according to claim 12, wherein pressure forming the first protective layer is higher than pressure forming the recess.

17. The method for manufacturing the semiconductor device according to claim 12 further comprising after the first etching and before forming the first modified layer:
forming an oxide layer on the recess by performing a plasma treatment using oxygen gas.

18. The method for manufacturing the semiconductor device according to claim 17, wherein a temperature forming the first modified layer is higher than a temperature forming the recess, and pressure forming the first modified layer is higher than pressure forming the recess.

19. The method for manufacturing the semiconductor device according to claim 12, wherein the film to be processed includes a silicon oxide film and a silicon nitride film, and the silicon oxide film and the silicon nitride film are alternately stacked.

20. The method for manufacturing the semiconductor device according to claim 12, wherein forming the recess and forming the first protective layer are performed in the same chamber.
